(19) United States
(12) Patent Application Publication
(10) Pub. No.: US 2024/0120243 A1
(43) Pub. Date: Apr. 11, 2024

(54) CIRCUIT BOARD AND PACKAGE SUBSTRATE COMPRISING SAME

(71) Applicant: LG INNOTEK CO., LTD., Seoul (KR)

(72) Inventors: Jong Bae SHIN, Seoul (KR); Moo Seong KIM, Seoul (KR); Soo Min LEE, Seoul (KR); Jae Hun JEONG, Seoul (KR)

(21) Appl. No.: 18/263,603

(22) PCT Filed: Apr. 26, 2021
(86) PCT No.: PCT/KR2021/005262

§ 371 Date: Jul. 31, 2023

(51) Int. Cl. H01L 23/13; H01L 21/48; H01L 23/498; H05K 1/18; H05K 3/46

(52) U.S. Cl. CPC H01L 23/13; H01L 21/4857; H01L 23/49822; H01L 23/49838; H05K 1/183; H05K 3/4644; H05K 2203/0195

(57) ABSTRACT

A circuit board according to an embodiment includes a first insulating layer; a second insulating layer disposed on the first insulating layer and including a cavity; and a plurality of pads disposed on the first insulating layer and having top surfaces exposed through the cavity; wherein the cavity of the second insulating layer includes: a bottom surface positioned higher than a top surface of the first insulating layer; and an inner wall extending from the bottom surface, wherein the inner wall is perpendicular to top or bottom surface of the second insulating layer, wherein the bottom surface of the cavity includes: a first bottom surface positioned lower than a top surface of the pad and positioned outside an arrangement region of the plurality of pads; and a second bottom surface positioned lower than the top surface of the pad and positioned inside the arrangement region of the plurality of pads, and wherein a height of the first bottom surface is different from a height of the second bottom surface.

### TECHNICAL FIELD

The embodiment relates to a circuit board and a package substrate comprising the same.

### Background Art

The circuit board has a structure in which a mounting position of each element is determined in order to densely mount various kinds of elements on a flat plate and a circuit pattern connecting elements is printed on a surface of the flat plate and fixed. Such a circuit board may have an embedded structure in which the elements are embedded therein.

Recently, in order to realize miniaturization and multifunctionality of electronic components, the circuit board has been used in a multi-layered structure capable of high-density integration.

In general, a conventional embedded circuit board forms a cavity for embedding an element using a drill bit, uses an auxiliary material such as a release film for mounting the element, or uses sandblasting to form a cavity for embedding the element.

However, in a cavity included in the conventional circuit board, an inclination angle of an inner wall is formed to be 150° or more with respect to a bottom surface of the cavity. Accordingly, there is a problem that a space required for forming the cavity is relatively increased by considering the inclination angle of the inner wall in order to provide a mounting space for an element in the cavity. Accordingly, the conventional circuit board has a problem that the degree of integration of the circuit is reduced, and the overall volume of the circuit board increases as the space for forming the cavity increases.

### DISCLOSURE

### Technical Problem

An embodiment relates to a circuit board capable of improving an inclination angle of an inner wall of a cavity, a package substrate, and a method of manufacturing the same.

In addition, the embodiment provides a circuit board, a package substrate, and a method of manufacturing the same capable of removing a stop layer required from a bottom surface of the cavity in the process of forming the cavity.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a first insulating layer; a second insulating layer disposed on the first insulating layer and including a cavity; and a plurality of pads disposed on the first insulating layer and having top surfaces exposed through the cavity; wherein the cavity of the second insulating layer includes: a bottom surface positioned higher than a top surface of the first insulating layer; and an inner wall extending from the bottom surface, wherein the inner wall is perpendicular to top or bottom surface of the second insulating layer, wherein the bottom surface of the cavity includes: a first bottom surface positioned lower than a top surface of the pad and positioned outside an arrangement region of the plurality of pads; and a second bottom surface positioned lower than the top surface of the pad and positioned inside the arrangement region of the plurality of pads, and wherein a height of the first bottom surface is different from a height of the second bottom surface.

In addition, the height of the first bottom surface is greater than the height of the second bottom surface.

In addition, at least one of the first bottom surface and the second bottom surface decreases in height from the outside to the inside.

In addition, a combined shape of the first bottom surface and the second bottom surface has a V-shape.

In addition, an upper width of the cavity is the same as a lower width of the cavity.

In addition, a thickness of the second insulating layer has a range of 5 um to 20 um.

In addition, the second insulating layer includes RCC (Resin Coated Copper).

In addition, the cavity includes an edge surface between the inner wall and the bottom surface, and the edge surface has a curved surface.

On the other hand, the package substrate according to the embodiment comprises a first insulating layer; a second insulating layer disposed on the first insulating layer and including a cavity; a plurality of pads disposed on the first insulating layer and having top surfaces exposed through the cavity; a connection part disposed on the plurality of pads; and an electronic device disposed on the connection part, wherein the cavity of the second insulating layer includes: a bottom surface positioned higher than a top surface of the first insulating layer; an inner wall extending from the bottom surface; and an edge surface between the inner wall and the bottom surface, wherein the inner wall is perpendicular to top or bottom surface of the second insulating layer, and wherein the edge surface has a curved surface.

In addition, the bottom surface of the cavity includes: a first bottom surface positioned lower than a top surface of the pad and positioned outside an arrangement region of the plurality of pads; and a second bottom surface positioned lower than the top surface of the pad and positioned inside the arrangement region of the plurality of pads, and wherein a height of the first bottom surface is different from a height of the second bottom surface.

In addition, the height of the first bottom surface is greater than the height of the second bottom surface, and at least one of the first bottom surface and the second bottom surface decreases in height from the outside to the inside.

In addition, a combined shape of the first bottom surface and the second bottom surface has a V-shape.

In addition, an upper width of the cavity is the same as a lower width of the cavity.

In addition, the second insulating layer includes RCC (Resin Coated Copper), and a thickness of the second insulating layer has a range of 5 um to 20 um.

In addition, the package substrate further comprises a molding layer disposed in the cavity and covering at least a portion of the electronic device.

On the other hand, a method of manufacturing the circuit board according to the embodiment comprises preparing a first insulating layer; forming a plurality of pads on a top surface of the first insulating layer; disposing a jig on the plurality of pads of the first insulating layer; forming a second insulating layer in a region other than a region where the jig is disposed among an upper region of the first insulating layer using the jig; forming a cavity in a region where the jig is disposed by separating the jig from the second insulating layer, wherein the second insulating layer includes RCC (Resin Coated Copper), wherein the cavity of the second insulating layer includes a bottom surface positioned higher than the top surface of the first insulating layer; and an inner wall extending from the bottom surface, wherein the inner wall is perpendicular to top or bottom surface of the second insulating layer, wherein the bottom surface of the cavity includes a first bottom surface positioned lower than the top surface of the pad and positioned outside an arrangement region of the plurality of pads; and a second bottom surface positioned lower than the top surface of the pad and positioned inside the arrangement region of the plurality of pads, and wherein a height of the first bottom surface is greater than a height of the second bottom surface.

In addition, at least one of the first bottom surface and the second bottom surface decreases in height from the outside to the inside, and a combined shape of the first bottom surface and the second bottom surface has a V shape, and an upper width of the cavity is the same as a lower width of the cavity.

In addition, the method further comprises de-smearing the cavity of the second insulating layer, and an edge surface between the inner wall and the bottom surface of the cavity has a curved surface.

### Advantageous Effects

According to an embodiment, the circuit board includes a cavity. In addition, the cavity of the circuit board has a non-penetrating structure rather than a structure penetrating the second insulating layer. In this case, the cavity exposes the pad disposed on a top surface of the first insulating layer. In this case, a bottom surface of the cavity is positioned lower than the top surface of the pad. Accordingly, in the embodiment, it is not necessary to form an additional stop layer on the top surface of the first insulating layer to form the cavity, and accordingly, it may omit processes such as the formation and removal of the stop layer. In addition, the embodiment may solve the reliability problem due to the change in thickness or shape of the pad that may occur in the process of removing the stop layer in the comparative example, and thereby improve product reliability.

In addition, the cavity of the circuit board in the embodiment includes a bottom surface and an inner wall. In this case, the bottom surface of the cavity may have different heights depending on positions. In other words, the bottom surface of the cavity may have a shape in which a height gradually decreases from the outside to the inside. According to this, when an additional molding layer is formed on the bottom surface of the cavity, a contact area with the molding layer may be increased, thereby improving product reliability.

In addition, the cavity of the circuit board in the embodiment is formed using a jig. In addition, a shape of the cavity may correspond to a shape of the jig. For example, an upper width and a lower width of the cavity may be equal to each other. In this case, an inclination angle of the inner wall of the cavity in the comparative example may be perpendicular to a main surface.

The above embodiment can reduce the inclination angle of the inner wall compared to the comparative example, and accordingly when the same device is disposed, the embodiment may minimize a space required for forming a cavity compared to the comparative example, thereby improving circuit integration. In other words, the embodiment may form the inclination angle of the inner wall substantially perpendicular, and accordingly, more circuits can be formed within the same area compared to the comparative example, and thus the overall volume of the circuit board can be reduced.

### DESCRIPTION OF DRAWINGS

FIG. 1A is a view showing a circuit board according to a first embodiment.

FIG. 1B is a view showing a circuit board according to a second embodiment.

FIG. 2A is an enlarged view of a cavity region of FIG. 1A.

FIG. 2B is an enlarged view of a cavity area of FIG. 1B.

FIG. 3 is a view showing a package substrate according to a first embodiment.

FIG. 4 is a view showing a package substrate according to a second embodiment.

FIGS. 5 to 9 are views illustrating a method of manufacturing the circuit board shown in FIG. 1B in order of process.

FIG. 10 is a view showing a package substrate according to a third embodiment.

FIGS. 11 to 14 are views illustrating a method of manufacturing the circuit board shown in FIG. 10 in order of process.

### MODES OF THE INVENTION

Hereinafter, embodiments of the present invention will be described in detail with reference to the accompanying drawings.

However, the spirit and scope of the embodiment is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art. In addition, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present invention, the terms such as first, second, A, B, (a), and (b) may be used.

These terms are only used to distinguish the elements from other elements, and the terms are not limited to the essence, order, or order of the elements. In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements. Furthermore, when expressed as “on (over)” or “under (below)”, it may include not only the upper direction but also the lower direction based on one element.

Hereinafter, embodiments of the present invention will be described in detail with reference to the accompanying drawings.

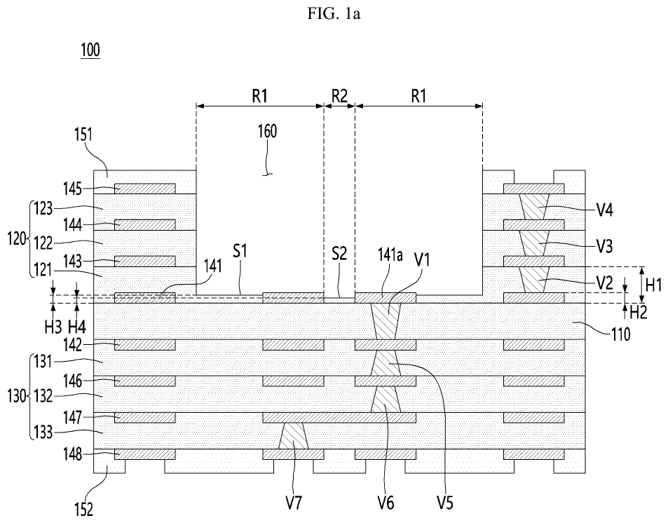

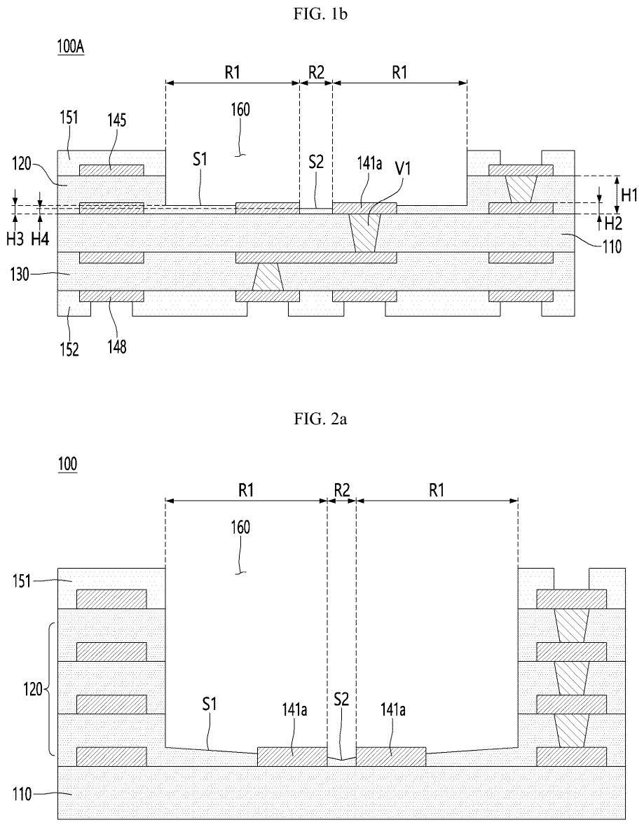

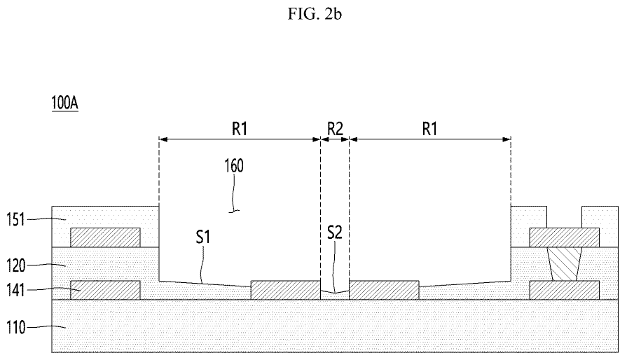

FIG. 1A is a view showing a circuit board according to a first embodiment, FIG. 1B is a view showing a circuit board according to a second embodiment, FIG. 2A is an enlarged view of a cavity region of FIG. 1A, and FIG. 2B is an enlarged view of a cavity area of FIG. 1B.

Referring to FIGS. 1A, 1B, 2A and 2B, the circuit board 100 includes a first insulating layer 110, a second insulating layer 120, a third insulating layer 130, circuit patterns 141, 141, 143, 144, 145, 146, 147, 148, vias V1, V2, V3, V4, V5, V6, V7, and protective layers 151 and 152.

The first insulating layer 110 may be an insulating layer disposed at a center of the circuit board 100.

The second insulating layer 120 is disposed on the first insulating layer 110.

In addition, the third insulating layer 130 is disposed under the first insulating layer 110.

In this case, although the first insulating layer 110 is illustrated as being disposed in a center layer in the entire laminated structure of the circuit board 100 in the drawing, the embodiment is not limited thereto. That is, the first insulating layer 110 may be disposed at a position biased toward an upper side in the entire laminated structure of the circuit board 100, or, alternatively, may be disposed at a position biased toward a lower side.

Here, referring to FIG. 1A, the second insulating layer 120 is disposed on the first insulating layer 110. In this case, the second insulating layer 120 has a structure of a plurality of layers. For example, the second insulating layer 120 may be included a second-first insulating layer 121 disposed on a top surface of the first insulating layer 110, a second-second insulating layer 122 disposed on a top surface of the second-first insulating layer 121, and a second-third insulating layer 123 disposed on a top surface of the second-second insulating layer 122. In this case, although it is illustrated that the second insulating layer 120 has a three-layer structure in the drawings, the embodiment is not limited thereto. That is, the second insulating layer 120 may be composed of two or less layers, or may be composed with a structure of four or more layers.

In addition, referring to FIG. 1A, the third insulating layer 130 is disposed under the first insulating layer 110. In this case, the third insulating layer 130 has a structure of a plurality of layers. For example, the third insulating layer 130 may include a third-first insulating layer 131 disposed under a bottom surface of the first insulating layer 110, a third-second insulating layer 132 disposed under a bottom surface of the third-first insulating layer 131, and a third-third insulating layer 133 disposed under a bottom surface of the third-second insulating layer 132. In this case, although it is illustrated that the third insulating layer 130 has a three-layer structure in the drawings, the embodiment is not limited thereto. That is, the second insulating layer 130 may be composed with two or less layers, or may be composed with a structure of four or more layers.

In addition, although the circuit board 100 is illustrated as having a seven-layer structure based on the insulating layer in the drawings, the embodiment is not limited thereto. For example, the circuit board 100 may have a number of layers of 6 or less based on the insulating layer, or may have a number of layers of 8 or more.

Meanwhile, in FIG. 1A, the second insulating layer 120 and the third insulating layer 130 have been described as having a structure of a plurality of layers, but are not limited thereto. For example, the second insulating layer 120 and the third insulating layer 130 may be composed of a single layer.

That is, as shown in FIG. 1B, one layer of the second insulating layer 120 and one layer of the third insulating layer 130 may be respectively disposed above and below the first insulating layer 110.

Accordingly, in FIG. 1A, a cavity (to be described later) is formed in the second insulating layer 120 composed of a plurality of layers, and thus the cavity may have a structure of a plurality of layers.

In addition, in FIG. 1B, a cavity may be formed in the second insulating layer 120 composed of a single layer.

That is, a difference between the first embodiment in FIG. 1A and the second embodiment in FIG. 1B is whether the second insulating layer is composed of a plurality of layers or a single layer. In addition, the difference between the first embodiment in FIG. 1A and the second embodiment in FIG. 1B is whether the cavity formed in the second insulating layer is formed by processing a plurality of layers or a single layer.

In other words, the second insulating layer 120 in the embodiment may be composed of a plurality of layers, or may be composed of a single layer. In addition, a cavity may be formed in the plurality of layers or the single layer of the second insulating layer 120.

The first insulating layer 110, the second insulating layer 120, and the third insulating layer 130 are substrates on which an electric circuit capable of changing wiring is formed, and it may include a circuit board and an insulating substrate made of an insulating material capable of forming circuit patterns on the surface thereof.

For example, the first insulating layer 110 may be rigid or flexible. For example, the first insulating layer 110 may include glass or plastic. In detail, the first insulating layer 110 may include chemically strengthened/semi-tempered glass such as soda lime glass or aluminosilicate glass, or reinforced or soft plastics such as polyimide (PI), polyethylene terephthalate (PET), propylene glycol (PPG), and polycarbonate (PC), or sapphire.

In addition, the first insulating layer 110 may include an optical isotropic film. For example, the first insulating layer 110 may include a cyclic olefin copolymer (COC), a cyclic olefin polymer (COP), an optical isotropic polycarbonate (polycarbonate, PC) or photoisotropic polymethyl methacrylate (PMMA).

In addition, the first insulating layer 110 may be bent while having a partially curved surface. That is, the first insulating layer 110 may be partially flat and partially curved while having a curved surface. In detail, the first insulating layer 110 may be curved while having a curved surface, or bent or curved while having a surface with random curvature.

In addition, the first insulating layer 110 may be a flexible substrate having a flexible property. In addition, the first insulating layer 110 may be a curved or bent substrate.

Meanwhile, the second insulating layer 120 and the third insulating layer 130 may be composed of RCC.

That is, all of the plurality of layers constituting the second insulating layer 120 and the third insulating layer 130 in the first embodiment may be composed of RCC.

In addition, each single layer constituting the second insulating layer 120 and the third insulating layer 130 in the second embodiment may be composed of RCC.

Accordingly, the second insulating layer 120 and the third insulating layer 130 may have a thickness of 5 μm to 20 μm. For example, when the second insulating layer 120 has a structure of a plurality of layers, each of the plurality of layers may have a thickness of 5 μm to 20 μm. In addition, when the second insulating layer 120 has a single layer, the thickness of the second insulating layer 120 of the single layer may be 5 μm to 20 μm.

That is, the insulating layer constituting the circuit board in the comparative example was composed of a prepreg (PPG) containing glass fibers. In this case, it is difficult to reduce the thickness of the glass fiber based on the PPG of the circuit board in the comparative example. This is because, when the thickness of the PPG decreases, the glass fiber included in the PPG may be electrically connected to a circuit pattern disposed on a surface of the PPG, and thus a crack risk is induced. Accordingly, in the case of reducing the thickness of the PPG of the circuit board in the comparative example, dielectric breakdown and damage to the circuit pattern may occur. Accordingly, the circuit board in the comparative example had a limitation in reducing the overall thickness due to the thickness of the glass fibers constituting the PPG.

Moreover, since the circuit board in the comparative example is comprised with the insulating layer only of PPG containing glass fiber, it has a high dielectric constant. However, in the case of a dielectric having a high dielectric constant, there is a problem that it is difficult to use for high frequency. That is, in the circuit board of the comparative example, since the dielectric constant of the glass fiber is high, the dielectric constant is broken in the high frequency band.

Accordingly, in the embodiment, an insulating layer is formed by using an RCC having a low dielectric constant, thereby reducing the thickness of the circuit board and providing a highly reliable circuit board in which signal loss is minimized even in a high frequency band.

Meanwhile, as the second insulating layer 120 in the embodiment is made of RCC, the thickness of the circuit board can be remarkably reduced compared to the comparative example made of PPG. Accordingly, in the embodiment, the thickness of the circuit board can be reduced by at least 5 μm compared to the comparative example by using the RCC made of the low-dielectric constant material.

However, even when using an RCC having a low dielectric constant of 2.7, which is 10% improved from the level of 3.0, which is the dielectric constant of PPG, the decrease in thickness is only 10% compared to the comparative example. Therefore, the embodiment allows it possible to provide an optimal circuit board by forming a cavity using a jig in a part where a chip such as an electronic device is mounted.

In this case, the first insulating layer 110 expresses the electrical wiring connecting the circuit components based on the circuit design as a wiring diagram, and may reproduce an electrical conductor on insulators. In addition, at least one of the first insulating layer 110, the second insulating layer 120, and the third insulating layer 130 is equipped with an electric component, it is possible to form a wiring connecting them in a circuit, and it can mechanically fix parts other than the electrical connection function of the parts.

Circuit patterns may be disposed on surfaces of the first insulating layer 110, the second insulating layer 120, and the third insulating layer 130. For example, when the second insulating layer 120 is formed of a single layer, the circuit pattern 143 may be disposed on a top surface of the single layer of the second insulating layer 120.

For example, when the second insulating layer 120 is composed of a plurality of layers, the first circuit pattern 141 may be disposed on a top surface of the first insulating layer 110. In this case, a plurality of first circuit patterns 141 may be disposed on the top surface of the first insulating layer 110 while being spaced apart from each other by a predetermined distance.

A second circuit pattern 142 may be disposed on a bottom surface of the first insulating layer 110. A plurality of second circuit patterns 142 may be disposed on the bottom surface of the first insulating layer 110 while being spaced apart from each other by a predetermined distance.

In addition, circuit patterns may be disposed on the surface of the second insulating layer 120. For example, a plurality of third circuit patterns 143 may be disposed on a top surface of the second-first insulating layer 121 to be spaced apart from each other by a predetermined distance. In addition, a plurality of fourth circuit patterns 144 may be disposed on a top surface of the second-second insulating layer 122 to be spaced apart from each other by a predetermined distance. In addition, a plurality of fifth circuit patterns 145 may be disposed on the top surface of the second-third insulating layer 123 to be spaced apart from each other by a predetermined distance.

In addition, circuit patterns may be disposed on the surface of the third insulating layer 130. For example, when the third insulating layer 130 is formed of a single layer, the circuit pattern 146 may be disposed on a bottom surface of the third insulating layer 130 of the single layer.

In addition, when the third insulating layer 130 is composed of a plurality of layers, a plurality of sixth circuit patterns 146 may be disposed on a bottom surface of the third-first insulating layer 131 to be spaced apart from each other by a predetermined distance. In addition, a plurality of seventh circuit patterns 147 may be disposed on a bottom surface of the third-second insulating layer 132 to be spaced apart from each other by a predetermined distance. In addition, a plurality of eighth circuit patterns 148 may be disposed on a bottom surface of the third-third insulating layer 133 to be spaced apart from each other by a predetermined distance.

Meanwhile, the first to eighth circuit patterns 141, 142, 143, 144, 145, 146, 147, and 148 as described above are wirings that transmit electrical signals, and may be formed of a metal material having high electrical conductivity. To this end, the first to eighth circuit patterns 141, 142, 143, 144, 145, 146, 147, and 148 may be formed of at least one metal material selected from gold (Au), silver (Ag), platinum (Pt), titanium (Ti), tin (Sn), copper (Cu), and zinc (Zn). In addition, the first to eighth circuit patterns 141, 142, 143, 144, 145, 146, 147, and 148 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first to eighth circuit patterns 141, 142, 143, 144, 145, 146, 147, and 148 may be formed of copper (Cu), which has high electrical conductivity and is relatively inexpensive.

The first to eighth circuit patterns 141, 142, 143, 144, 145, 146, 147, and 148 may be formed by an additive process, a subtractive process, a modified semi additive process (MSAP) and a semi additive process (SAP) method, which is a typical circuit board manufacturing process, and a detailed description thereof will be omitted herein.

Meanwhile, the first circuit pattern 141 may include a pad 141a that is exposed through a cavity 160 while being disposed on the top surface of the first insulating layer 110. The pad 141a may be electrically connected to an electronic device (described later) mounted in the cavity 160. For example, the pad 141a may be a wire bonding pad connected to an electronic device mounted in the cavity 160 through a wire. Alternatively, the pad 141a may be a flip-chip bonding pad directly connected to a terminal of an electronic device mounted in the cavity 160. In this case, the pad 141a may include a first pad and a second pad spaced apart from each other by a predetermined distance. This will be described in more detail below.

Meanwhile, each of the first to eighth circuit patterns 141, 142, 143, 144, 145, 146, 147, and 148 may include a pattern connected to a via for interlayer conduction, a pattern for signal transmission, and a pad connected to an electronic device and the like.

Vias V1, V2, V3, V4, V5, V6, and V7 that electrically connect circuit patterns disposed on different layers to each other may be disposed in the first insulating layer 110, the second insulating layer 120, and the third insulating layer 130. The vias V1, V2, V3, V4, V5, V6, and V7 may be disposed to pass through at least one of the first insulating layer 110, the second insulating layer 120, and the third insulating layer 130. In addition, both ends of the vias V1, V2, V3, V4, V5, V6, and V7 are respectively connected to circuit patterns disposed on different insulating layers, and thus an electrical signal may be transmitted.

A first via V1 may be disposed in the first insulating layer 110. The first via V1 may be disposed to pass through top and bottom surfaces of the first insulating layer 110. The first via V1 may electrically connects the first circuit pattern 141 disposed on the top surface of the first insulating layer 110 and the second circuit pattern 142 disposed on the bottom surface of the first insulating layer 110.

A plurality of vias may be disposed in the second insulating layer 120. That is, the second via V2 may be disposed in the second-first insulating layer 121. The second via V2 may be electrically connected the first circuit pattern 141 disposed on the top surface of the first insulating layer 110 and the third circuit pattern 143 disposed on the top surface of the second-first insulating layer 121.

In addition, a third via V3 may be disposed in the second-second insulating layer 122. The third via V3 may be electrically connected the fourth circuit pattern 144 disposed on the top surface of the second-second insulating layer 122 and the third circuit pattern 143 disposed on the top surface of the second-first insulating layer 121.

In addition, a fourth via V4 may be disposed in the second-third insulating layer 123. The fourth via V4 may be electrically connected the fifth circuit pattern 145 disposed on the top surface of the second-third insulating layer 123 and the fourth circuit pattern 144 disposed on the top surface of the second-second insulating layer 122.

In addition, when the second insulating layer 120 is formed of a single layer, only the second via V2 may be disposed in the single layer of the second insulating layer 120.

A plurality of vias may be disposed in the third insulating layer 130. That is, a fifth via V5 may be disposed in the third-first insulating layer 131. The fifth via V5 may be electrically connected the second circuit pattern 142 disposed on the bottom surface of the first insulating layer 110 and the sixth circuit pattern 146 disposed on the bottom surface of the third-first insulating layer 131.

In addition, a sixth via V6 may be disposed in the third-second insulating layer 132. The sixth via V6 may be electrically connected the seventh circuit pattern 147 disposed on the bottom surface of the third-second insulating layer 132 and the sixth circuit pattern 146 disposed on the bottom surface of the third-first insulating layer 131.

In addition, a seventh via V7 may be disposed in the third-third insulating layer 133. The seventh via V7 may be electrically connected the eighth circuit pattern 148 disposed on the bottom surface of the third-third insulating layer 133 and the seventh circuit pattern 147 disposed on the bottom surface of the third-second insulating layer 132.

In addition, when the third insulating layer 130 is formed of a single layer, only the third via V3 may be disposed in the single layer of the second insulating layer 120.

Meanwhile, the vias V1, V2, V3, V4, V5, V6, and V7 may pass through only one insulating layer among the first insulating layer 110, the second insulating layer 120, and the third insulating layer 130, or alternatively, may be disposed while passing through a plurality of insulating layers in common. Accordingly, the vias V1, V2, V3, V4, V5, V6, and V7 may connect circuit patterns disposed on the surface of the insulating layer that are at least two or more apart from each other, rather than the neighboring insulating layers.

Meanwhile, the vias V1, V2, V3, V4, V5, V6, and V7 may be formed by filling the inside of a through hole (not shown) passing through at least one insulating layer among the plurality of insulating layers with a conductive material.

The through hole may be formed by any one of machining methods, including mechanical, laser, and chemical processing. When the through hole is formed by mechanical processing, methods such as milling, drilling, and routing may be used, and when the through hole is formed by laser processing, a UV or CO₂ laser method may be used, and when the through hole is formed by chemical processing, drugs containing amino silane, ketones, etc. may be used, and the like, thereby at least one insulating layer among the plurality of insulating layers may be opened.

On the other hand, the processing by the laser is a cutting method that takes the desired shape to melt and evaporate a part of the material by concentrating optical energy on the surface, it can easily process complex formations by computer programs, and can process composite materials that are difficult to cut by other methods.

In addition, the processing by the laser can have a cutting diameter of at least 0.005 mm, and has a wide advantage in a range of possible thicknesses.

As the drill for the laser processing, it is preferable to use a YAG (Yttrium Aluminum Garnet) laser, a CO₂ laser, or an ultraviolet (UV) laser. The YAG laser is a laser that can process both the copper foil layer and the insulating layer, and the CO₂ laser is a laser that can process only the insulating layer.

When the through hole is formed, the vias V1, V2, V3, V4, V5, V6, and V7 may be formed by filling the inside of the through hole with a conductive material. Metal materials forming the vias V1, V2, V3, V4, V5, V6, and V7 may be any one material selected from Cu, Ag, Sn, Au, Ni, and Pd, and the metal material may be filled using any one or a combination of electroless plating, electrolytic plating, screen printing, sputtering, evaporation, ink jetting and dispensing.

Meanwhile, protective layers 151 and 152 may be disposed on the surface of an outermost insulating layer among the first insulating layer 110, the second insulating layer 120, and the third insulating layer 130. For example, the first protective layer 151 may be disposed on the top surface of the insulating layer disposed on the uppermost of the plurality of insulating layers. For example, the first protective layer 151 may be disposed on the top surface of the second-third insulating layer 123 disposed on the uppermost portion of the second insulating layer 120. In addition, a second protective layer 152 may be disposed on a bottom surface of the insulating layer disposed at the lowermost portion among the plurality of insulating layers. For example, the second protective layer 152 may be disposed on a bottom surface of the third-third insulating layer 133 disposed at the lowermost portion of the third insulating layer 130.

In addition, when the second insulating layer 120 and the third insulating layer 130 are each composed of a single layer, the first protective layer 151 may be disposed at the top surface of the second insulating layer 120, and the second protective layer 152 may be disposed at the lower surface of the third insulating layer 130.

The first protective layer 151 and the second protective layer 152 may each have an opening. For example, the first protective layer 151 may have an opening exposing the surface of the fifth circuit pattern to be exposed among the fifth circuit patterns 145 disposed on the top surface of the second-third insulating layer 123.

In addition, the second protective layer 152 may have an opening exposing the surface of the eighth circuit pattern to be exposed among the eighth circuit patterns 148 disposed on the bottom surface of the third-third insulating layer 133.

The first protective layer 151 and the second protective layer 152 may include an insulating material. The first protective layer 151 and the second protective layer 152 may include various materials that can be cured by heating after being applied to protect the surface of the circuit patterns. The first protective layer 151 and the second protective layer 152 may be resist layers. For example, the first protective layer 151 and the second protective layer 152 may be a solder resist layer including an organic polymer material. For example, the first protective layer 151 and the second protective layer 152 may include an epoxy acrylate-based resin. In detail, the first protective layer 151 and the second protective layer 152 may include a resin, a curing agent, a photo initiator, a pigment, a solvent, a filler, an additive, an acryl-based monomer, and the like. However, the embodiment is not limited thereto, and the first protective layer 151 and the second protective layer 152 may be any one of a photo solder resist layer, a cover-lay, and a polymer material.

A thickness of the first protective layer 151 and the second protective layer 152 may be 1 μm to 20 μm. The thickness of the first protective layer 151 and the second protective layer 152 may be 1 μm to 15 μm. For example, the thickness of the first protective layer 151 and the second protective layer 152 may be 5 μm to 20 μm. When the thickness of the first protective layer 151 and the second protective layer 151 is greater than 20 μm, the thickness of the circuit board may increase. When the thickness of the first protective layer 151 and the second protective layer 152 is less than 1 μm, the reliability of the circuit pattern may be deteriorated.

Meanwhile, a cavity 160 may be formed in the second insulating layer 120. In this case, the cavity 160 may be disposed in the second insulating layer 120 composed of a plurality of layers. In this case, the cavity 160 may be provided to pass through at least one insulating layer among the second insulating layers 120 composed of the plurality of layers, and may be provided to non-pass through at least another insulating layer.

That is, a general cavity is provided through the insulating layer. Accordingly, the insulating layer overlapping the cavity 160 in the horizontal direction does not exist at the position where the cavity 160 is to be disposed. For example, the cavity in the comparative example is disposed to pass through the entire second insulating layer 120. For example, the cavity in the comparative example is formed penetrating from the top surface to the lower surface of the second insulating layer 120.

Unlike this, the cavity of the embodiment passes through at least one insulating layer among the insulating layers vertically overlapping the cavity 160 and does not pass through at least another insulating layer at the position where the cavity is to be disposed.

That is, in the first embodiment, the cavity 160 is disposed in the second insulating layer 120. That is, the cavity 160 is provided in the second-first insulating layer 121, the second-second insulating layer 122, and the second-third insulating layer 123. In addition, the cavity 160 in the second embodiment is provided in the second insulating layer 120 composed of one layer.

Hereinafter, the structure of the cavity formed in the second insulating layer 120 composed of a plurality of layers as in the first embodiment will be described first.

In this case, in the structure of the circuit board of the comparative example, the cavity is disposed to pass through all of the second-first insulating layer 121, the second-second insulating layer 122, and the second-third insulating layer 123. Accordingly, in the circuit board of the comparative example, the top surface of the first insulating layer in the region vertically overlapping with the cavity is exposed. That is, the second insulating layer (more specifically, the second-first insulating layer) does not exist on the top surface of the first insulating layer vertically overlapping with the cavity in the circuit board of the comparative example.

In contrast, the cavity 160 in the circuit board 100 in the embodiment shown in FIGS. 1A and 2A may be provided without passing through the second-third insulating layer 123 while passing through the second-first insulating layer 121 and the second-second insulating layer 122.

That is, the cavity 160 may include a first part P1 disposed in the second-first insulating layer 121, a second part P2 disposed in the second-second insulating layer 122, and a third part P3 disposed in the second-third insulating layer 123. Here, as the second insulating layer 122 in the embodiment has a three-layer structure, the cavity 160 is illustrated as being composed of the first to third parts P1, P2, and P3, but the embodiment is not limited thereto. For example, when the second insulating layer 120 has a two-layer structure, the cavity 160 may include only the first and second parts. For example, when the second insulating layer 122 has a five-layer structure, the cavity 160 may include first to fifth parts. However, the cavity 160 in the embodiment is characterized in that the lowermost part has a groove shape rather than a through hole shape.

The first part P1 may be provided in the second-first insulating layer 121. In this case, the first part P1 may be a groove provided in the second-first insulating layer 121 and forming a lower region of the cavity 160.

The second part P2 may be provided in the second-second insulating layer 122. The second part P2 is provided in the second-second insulating layer 122 and may be a through hole forming a central region of the cavity 160.

The third part P3 may be provided in the second-third insulating layer 123. The third part P3 is provided in the second-third insulating layer 123 and may be a through hole forming an upper region of the cavity 160.

That is, the cavity 160 may be formed of a combination of the first part P1, the second part P2, and the third part P3. In this case, a thickness of the first part P1 may be smaller than the thickness of the second-first insulating layer 121. Accordingly, the cavity 160 may be formed without passing the second-first insulating layer 121.

In other words, the second-first insulating layer 121 may include a first portion disposed on a region vertically overlapping with the cavity 160 and a second portion excluding the first portion. In addition, a thickness H3 and H4 of the first portion may be different from a thickness H1 of the second portion.

Preferably, the thickness H1 of the second portion may be the thickness of the second-first insulating layer 121.

The second portion may have a thickness of 5 μm to 20 μm. For example, the thickness of the second portion corresponds to the thickness of the second-first insulating layer 121 composed of one layer of RCC, and thus may have a thickness of 5 μm to 20 μm.

A thickness H3 and H4 of the first portion may be smaller than a thickness H1 of the second portion. The thickness H3 and H4 of the first portion may be determined by a thickness H2 of the pad 141a. Preferably, the thickness H2 of the first portion may be smaller than the thickness H2 of the pad 141a.

Preferably, the thickness H2 of the pad 141a may be smaller than the thickness H1 of the second portion. For example, the thickness H2 of the pad 141a may be 5 μm to 10 μm.

In addition, a thickness H3 and H4 of the first portion may be smaller than a thickness H3 of the pad 141a. For example, the thickness H3 and H4 of the first portion may be 3 μm to 8 μm. Accordingly, the first portion of the second-first insulating layer 121 is disposed on the first insulating layer 110. In this case, the first portion of the second-first insulating layer 121 may expose the top surface of the pad 141a disposed on the first insulating layer 110. Meanwhile, the thicknesses H3 and H4 of the first portion may be different for each region. For example, the thickness of the first portion may change from the outside to the inside. For example, the first portion may gradually decrease in width from the outer side to the inner side.

That is, in the embodiment, in order to mount the electronic device, the cavity 160 is not formed through the second insulating layer 120, the cavity 160 is formed in a state in which at least a portion of the second insulating layer 120 (the first portion of the second-first insulating layer 121) remains on the first insulating layer 110.

In this case, the thickness H3 and H4 of a portion of the remaining second insulating layer 120 is smaller than the thickness H2 of the pad 141a to be exposed on the cavity 160. Accordingly, in an embodiment, the cavity 160 may be formed while maintaining the shape of the pad 141a without affecting the mounting of the electronic device on the pad 141a.

That is, in the prior art, in order to form the cavity in the plurality of insulating layers as described above, the cavity forming process was performed in a state in which a protective layer or a stop layer was disposed on the first insulating layer. Accordingly, in the prior art, the cavity could be formed to a desired depth (a depth passing all of the second insulating layer). However, in the related art, after the cavity is formed, an etching process of removing the protective layer or the stop layer has to be performed. Accordingly, in the prior art, a portion of the pad disposed on the first insulating layer is also removed during the etching process of removing the protective layer or the stop layer, which may cause a problem in reliability of the pad. In this case, the thickness of the protective layer or stop layer required for sand blasting or laser processing is 3 um to 10 um, and accordingly, there is a problem in that an amount corresponding to the thickness of the protective layer or the stop layer among the total thickness of the pad is removed during the etching process. In addition, in the prior art, the cavity were formed using a laser or an etching process, and thus the upper width of the cavity was different from the lower width of the cavity. For example, a conventional cavity has a trapezoidal shape in which a width gradually decreases from an upper side to a lower side.

Accordingly, in the embodiment, the cavity can be easily formed without forming the protective layer or the stop layer, thereby solving the reliability problem that occurs during the process of removing the protective layer or the stop layer. In addition, the upper width of the cavity in the embodiment may be the same as the lower width of the cavity. This is because the cavity is formed using a jig (to be described later) having the same upper and lower widths.

Meanwhile, referring to FIGS. 1A and 2A, the cavity 160 includes an inner wall and a bottom surface S1 and S2.

The bottom surface S1 and S2 of the cavity 160 may have a predetermined surface roughness. In this case, in the embodiment, an additional process is not performed so that the bottom surface S1 and S2 of the cavity 160 have a predetermined surface roughness, and the bottom surfaces S1 and S2 may have a predetermined surface roughness by forming the second insulating layer 120 in a state where the jig is disposed.

In other words, the bottom surfaces S1 and S2 of the cavity 160 may mean the top surface of the first portion of the second-first insulating layer 121. Also, the height of the top surface of the first portion of the second-first insulating layer 121 is not constant and may vary depending on the position. Preferably, the height of the top surface of the first portion of the second-first insulating layer 121 may change from an edge portion to an inner portion. Preferably, the top surface of the first portion of the second-first insulating layer 121 may decrease in height as the distance from the inner wall increases. In other words, a depth of the cavity 160 may vary depending on the position. For example, the depth of the cavity 160 may change from the outside to the inside. For example, the depth of the cavity 160 may gradually increase from the outside to the inside.

In this case, the embodiment uses a rectangular jig to form the cavity 160, and because of this, the inner wall may be perpendicular to the main surface of the second insulating layer. Preferably, the cavity 160 may have a shape in which an upper width and a lower width are equal to each other.

In this case, the height of the first portion of the second insulating layer or the depth of the cavity 160 may be determined by the position of the pad 141a.

That is, the bottom surface of the cavity 160 may include a first region R1 and a second region R2. The first region R1 may be an outer region of the cavity 160. For example, the first region R1 may be an edge region of the cavity 160. The second region R2 may be an inner region of the cavity 160. For example, the second region R2 may be a center region of the cavity 160.

In this case, the first region R1 and the second region R2 may be determined based on a region in which the plurality of pads 141a are disposed. For example, the first region R1 may be an outer region of an arrangement region of the plurality of pads 141a. For example, the second region R2 may be an inner of an arrangement region of the plurality of pads 141a. For example, the second region R2 may be a region between the plurality of pads 141a. Also, the first region R1 may be a region other than a region between the plurality of pads 141a. More specifically, the first region R1 may be an outer region of the bottom surface. In addition, the second region R2 may be a center region of the bottom surface. That is, the first region R1 may be provided surrounding the second region R2.

Accordingly, the bottom surface of the cavity 160 may include a first bottom surface S1 corresponding to the first region R1 and a second bottom surface S2 corresponding to the second region R2.

In addition, the first bottom surface S1 and the second bottom surface S2 may have different heights.

Preferably, the first bottom surface S1 and the second bottom surface S2 have heights lower than that of the pad 141a and may be disposed on a region in which a cavity is formed among the top surfaces of the first insulating layer.

As described above, the pad 141a may have a second height H2.

In addition, the first bottom surface S1 may have a third height H3 smaller than the second height H2. In addition, the second bottom surface S2 may have a fourth height H4 smaller than the second height H2 and the third height H3.

The third height H3 may have a level of 95% or less of the second height H2. In this case, the first bottom surface S1 may have different heights for each position. Accordingly, the third height H3 may mean an average height of the first bottom surface S1. Alternatively, the third height H3 may mean a greatest height value among heights of each position of the first bottom surface S1.

In this case, as described above, the first bottom surface S1 has different heights for each position. That is, the third height H3 of the first bottom surface S1 may have different values depending on positions.

Preferably, the height of the first bottom surface S1 may decrease from the outside to the inside. For example, the first bottom surface S1 may have the greatest height at a portion closest to the inner wall. For example, the first bottom surface S1 may have the smallest height at a portion adjacent to the second bottom surface S2.

In addition, the second bottom surface S2 may have a height smaller than that of the first bottom surface S1 and may be positioned between the plurality of pads 141a within the cavity 160.

In this case, the second bottom surface S2 may have a height smaller than a height of the first bottom surface S1. Furthermore, the second bottom surface S2 may have different heights depending on positions. That is, the fourth height H4 of the second bottom surface S2 may have different values depending on positions.

Preferably, the height of the second bottom surface S2 may decrease from the outside to the inside. For example, the second bottom surface S2 may have the greatest height at a portion adjacent to the inner side of the pad 141a (or a portion adjacent to the first bottom surface). And, the second bottom surface S2 may have the smallest height in a center portion. That is, a cross section of the second bottom surface S2 may have a V-shape in which the height gradually decreases from the outside to the inside. In addition, a cross section of the first bottom surface S1 may have a V-shape in which the height decreases from the outside to the inside.

That is, in the embodiment, the cavity 160 is formed using a jig. Accordingly, the cavity 160 in the above embodiment may have the same upper width and lower width.

In this case, the second insulating layer 120 in the embodiment may be formed in a state in which a jig is disposed on a region where the cavity 160 is to be formed. Accordingly, the second insulating layer 120 may be formed in the remaining regions except for the region where the jig is disposed. That is, the second insulating layer 120 may be formed by opening the region where the jig is disposed.

Here, a pad 141a is disposed in a region where the cavity 160 is to be formed. Also, the jig may be positioned on the pad 141a. At this time, the pad 141a has a certain height, and accordingly, the jig may be spaced apart from each other at a predetermined interval by the height of the pad 141a, rather than contacting the top surface of the first insulating layer 110, in the region where the cavity 160 is to be formed. Further, the second insulating layer 120 may penetrate into a region between the first insulating layer and the jig in a state in which the jig is disposed. At this time, when the second insulating layer 120 is laminated, the largest amount of resin penetrates into the relatively close first region R1, and accordingly, it may have the greatest height at the outermost portion of the first bottom surface S1. In addition, when the second insulating layer 120 is laminated, the penetration amount of the resin gradually decreases as the distance from the first region R1 increases, and accordingly, the center portion of the second bottom surface S2 may have the smallest height.

Meanwhile, the cavity in the second embodiment may be formed in the second insulating layer 120 composed of a single layer.

That is, the cavity 160 in the circuit board 100 according to the second embodiment may be formed without penetrating the second insulating layer 120.

In other words, the second insulating layer 120 may include a first portion in which the cavity 160 is formed and a second portion excluding the first portion. In addition, the thickness H3 and H4 of the first portion may be different from the thickness H1 of the second portion.

Preferably, the thickness H1 of the second portion may correspond to the thickness of the second insulating layer 120.

The second portion may have a thickness of 5 μm to 20 μm. For example, the thickness of the second portion corresponds to the thickness of the second insulating layer 120 composed of one layer of RCC, and thus may have a thickness of 5 μm to 20 μm.

A thickness H3 and H4 of the first portion may be smaller than a thickness H1 of the second portion. The thickness H3 and H4 of the first portion may be determined by the thickness H2 of the pad 141a. Preferably, the thickness H3 and H4 of the first portion may be smaller than the thickness H2 of the pad 141a.

Preferably, the thickness H2 of the pad 141a may be smaller than the thickness H1 of the second portion. For example, the thickness H2 of the pad 141a may be 5 μm to 10 μm.

In addition, the thickness H3 and H4 of the first portion may be smaller than the thickness H3 of the pad 141a. For example, the thickness H3 and H4 of the first portion may be 3 μm to 8 μm. Thus, the first portion of the second insulating layer 120 is disposed on the first insulating layer 110. In this case, the first portion of the second insulating layer 120 may expose the top surface of the pad 141a disposed on the first insulating layer 110. Meanwhile, the thicknesses H3 and H4 of the first portion may be different for each region. For example, the thickness of the first portion may change from the outside to the inside. For example, the first portion may gradually decrease in width from the outer side to the inner side.

That is, in the embodiment, the cavity 160 is formed so that the cavity 160 does not penetrate the second insulating layer 120 and at least a portion of the second insulating layer 120 remains on the first insulating layer 110.

In this case, the thickness H3 and H4 of the remaining portion of the second insulating layer 120 is smaller than the thickness H2 of the pad 141a to be exposed on the cavity 160. Accordingly, in the embodiment, the cavity 160 may be formed while maintaining the shape of the pad 141a without affecting the mounting of the electronic device on the pad 141a.

In addition, referring to FIGS. 1B and 2B, the cavity 160 includes inner walls and a bottom surface S1 and S2.

The bottom surface S1 and S2 of the cavity 160 may have a predetermined surface roughness. In this case, in the embodiment, an additional process is not performed so that the bottom surface S1 and S2 of the cavity 160 have a predetermined surface roughness, the bottom surfaces S1 and S2 may have a certain surface roughness by forming the second insulating layer 120 in a state where the jig is disposed.

In other words, the bottom surface S1 and S2 of the cavity 160 may mean the top surface of the first portion of the second insulating layer 120. In addition, the height of the top surface of the first portion of the second insulating layer 121 is not constant and may have a deviation depending on the position. Preferably, the height of the top surface of the first portion of the second insulating layer 121 may change from the edge portion to the inner portion. Preferably, the top surface of the first portion of the second insulating layer 120 may decrease in height as the distance from the inner wall increases. In other words, the depth of the cavity 160 may vary depending on the position. For example, the depth of the cavity 160 may change from the outside to the inside. For example, the depth of the cavity 160 may gradually increase from the outside to the inside.

In this case, since the rectangular jig is used in forming the cavity 160 in the embodiment, the inner wall may be perpendicular to the main surface of the second insulating layer. Preferably, the cavity 160 may have a shape in which an upper width and a lower width are equal to each other.

In this case, the height of the first portion of the second insulating layer or the depth of the cavity 160 may be determined by the position of the pad 141a.

That is, the bottom surface of the cavity 160 may include a first region R1 and a second region R2. The first region R1 may be an outer region of the cavity 160. For example, the first region R1 may be an edge region of the cavity 160. The second region R2 may be an inner region of the cavity 160. For example, the second region R2 may be a center region of the cavity 160.

In this case, the first region R1 and the second region R2 may be determined based on a region in which the plurality of pads 141a are disposed. For example, the first region R1 may be an outer region of an arrangement region of the plurality of pads 141a. For example, the second region R2 may be an inner region of a region in which the plurality of pads 141a are disposed. For example, the second region R2 may be a region between the plurality of pads 141a. Also, the first region R1 may be a region other than a region between the plurality of pads 141a. More specifically, the first region R1 may be an outer region of the bottom surface. Also, the second region R2 may be a center region of the bottom surface. That is, the first region R1 may be formed surrounding the second region R2.

Accordingly, the bottom surface of the cavity 160 may include a first bottom surface S1 corresponding to the first region R1 and a second bottom surface S2 corresponding to the second region R2.

In addition, the first bottom surface S1 and the second bottom surface S2 may have different heights.

Preferably, the first bottom surface S1 and the second bottom surface S2 have heights lower than that of the pad 141a and may be disposed on a region in which a cavity is formed among the top surfaces of the first insulating layer.

As described above, the pad 141a may have a second height H2.

In addition, the first bottom surface S1 may have a third height H3 smaller than the second height H2. In addition, the second bottom surface S2 may have a fourth height H4 smaller than the second height H2 and the third height H3.

The third height H3 may have a level of 95% or less of the second height H2. In this case, the first bottom surface S1 may have different heights for each position. Accordingly, the third height H3 may mean an average height of the first bottom surface S1. Alternatively, the third height H3 may mean the greatest height value among heights of each position of the first bottom surface S1.

In this case, as described above, the first bottom surface S1 has different heights for each position. That is, the third height H3 of the first bottom surface S1 may have different values depending on positions.

Preferably, the height of the first bottom surface S1 may decrease from the outside to the inside. For example, the first bottom surface S1 may have the greatest height at a portion closest to the inner wall. For example, the first bottom surface S1 may have the smallest height at a portion adjacent to the second bottom surface S2.

In addition, the second bottom surface S2 may have a height smaller than that of the first bottom surface S1 and may be positioned between the plurality of pads 141a within the cavity 160.

In this case, the second bottom surface S2 may have a height smaller than that of the first bottom surface S1. Furthermore, the second bottom surface S2 may have different heights depending on positions. That is, the fourth height H4 of the second bottom surface S2 may have different values depending on positions.

Preferably, the height of the second bottom surface S2 may decrease from the outside to the inside. For example, the second bottom surface S2 may have the greatest height at a portion adjacent to the inner side of the pad 141a (or a portion adjacent to the first bottom surface). And, the second bottom surface S2 may have the smallest height in the center portion. That is, the cross section of the second bottom surface S2 may have a V-shape in which the height gradually decreases from the outside to the inside. In addition, the cross section of the first bottom surface S1 may have a V-shape in which the height decreases from the outside to the inside.

That is, in the circuit board 100 according to the first embodiment according to FIGS. 1A and 2A, the second insulating layer 120 is composed of a plurality of RCC layers, and a cavity 160 is formed in the second insulating layer 120 composed of the plurality of layers. And, in the circuit board 100A in the second embodiment according to FIGS. 1B and 2B, the second insulating layer 120 is composed of a single RCC layer, and a cavity 160 is formed in the single-layer second insulating layer 120.

Hereinafter, a package substrate including the structure of the circuit board in the first embodiment will be described.

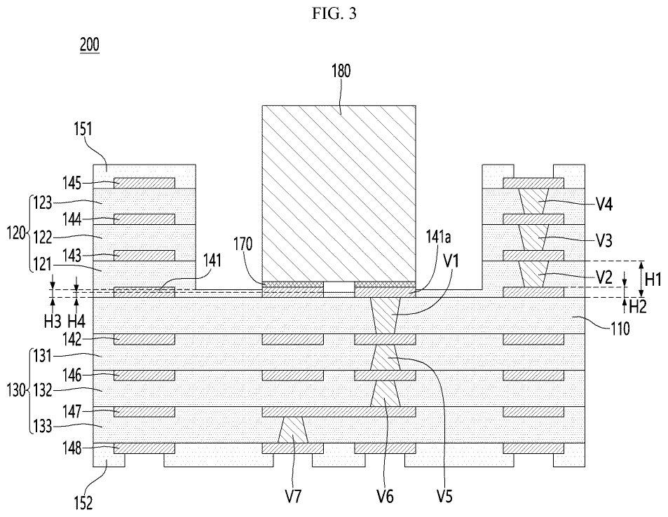

FIG. 3 is a view showing a package substrate according to a first embodiment.

Referring to FIG. 3, a package substrate 200 in the embodiment includes the circuit board 100 shown in FIG. 1 and the electronic device 180 mounted in the cavity 160 of the circuit board 100.

The circuit board 100 described with reference to FIGS. 1A, 1B, 2A and 2B may be used as a package substrate 200 for mounting the electronic device 180.

In this case, since the circuit board 100 has already been described in detail above, a description thereof will be omitted.

The circuit board 100 includes a cavity 160, and a pad 141a may be exposed in the cavity 160. In this case, the second-first insulating layer 121 may be disposed in a region other than the area where the pad 141a is formed within the cavity 160. However, the height of the first portion of the second-first insulating layer 121 is lower than the height of the pad 141a. Accordingly, the electronic device 180 may be stably mounted on the pad 141a without being affected by the first portion of the second insulating layer. In other words, when the height of the first portion of the second-first insulating layer 121 is higher than the height of the pad 141a, the electronic device 180 may be mounted on the pad 141a in an inclined state, and furthermore, a defect may occur in an electrical connection state with the pad 141a.

In this case, the electronic device 180 may be electronic components such as chips, which may be divided into active devices and passive devices. In addition, the active device is a device that actively uses a non-linear portion, and the passive device refers to a device that does not use the non-linear characteristic even though both linear and non-linear characteristics exist. In addition, the passive device may include a transistor, an IC semiconductor chip, and the like, and the passive device may include a capacitor, a resistor, an inductor, and the like. The passive device is mounted on a general circuit board to increase a signal processing speed of a semiconductor chip, which is an active device, or to perform a filtering function.

Meanwhile, a connection portion 170 may be disposed on the pad 141a. A planar shape of the connection portion 170 may be a quadrangle. The connection portion 170 is disposed on the pad 141a and electrically connects the electronic device 180 and the pad 141a while fixing the electronic device 180. To this end, the pad 141a may be formed of a conductive material. For example, the connection portion 170 may be a solder ball. In the connection portion 170, a heterogeneous material may be contained in the solder. The solder may be composed of at least one of SnCu, SnPb, and SnAgCu. In addition, the heterogeneous material may include any one of Al, Sb, Bi, Cu, Ni, In, Pb, Ag, Sn, Zn, Ga, Cd, and Fe.

Meanwhile, the top surface of the electronic device 180 may be positioned higher than the surface of the uppermost layer of the circuit board 100. However, the embodiment is not limited thereto, and depending on the type of the electronic device 180, the top surface of the electronic device 180 may be disposed at the same height as the surface of the uppermost layer of the circuit board 100 or may be positioned lower otherwise.

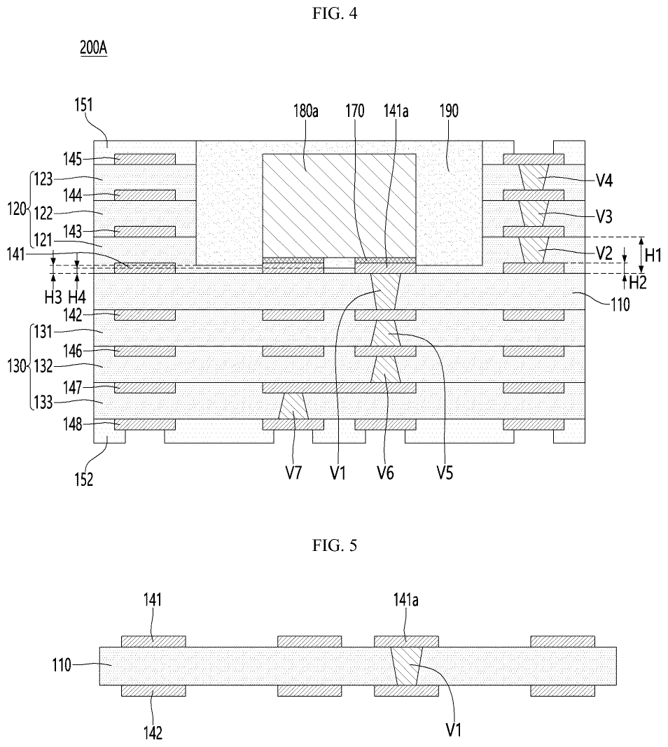

FIG. 4 is a view showing a package substrate according to a second embodiment.

Referring to FIG. 4, the package substrate 200A in the embodiment includes the circuit board 100 and an electronic device 180a mounted in the cavity 160 of the circuit board 100.

In addition, the package substrate 200A further includes a molding layer disposed in the cavity 160 to cover the electronic device 180a.

The molding layer 190 may be selectively disposed in the cavity 160 to protect the electronic device 180a mounted in the cavity 160.

The molding layer 190 may be formed of a molding resin, for example, EMC (Epoxy Molding Compound). However, the embodiment is not limited thereto, and the molding layer 190 may be formed of various other molding resins in addition to EMC.

The circuit board 100 may be used as a package substrate 200A for mounting the electronic device 180a.

The circuit board 100 includes a cavity 160, and a pad 141a may be exposed in the cavity 160. In this case, the second-first insulating layer 121 may be disposed in a region other than the area where the pad 141a is formed within the cavity 160. However, the height of the first portion of the second-first insulating layer 121 is lower than the height of the pad 141a. Accordingly, the electronic device 180a may be stably mounted on the pad 141a without being affected by the first portion of the second-first insulating layer 121. In other words, when the height of the first portion of the second-first insulating layer 121 is higher than the height of the pad 141a, the electronic device 180a may be mounted on the pad 141a in an inclined state, and furthermore, a defect may occur in an electrical connection state with the pad 141a.

In the embodiment, the molding layer 190 is disposed in contact with the inner wall and bottom surfaces S1 and S2 of the cavity 160. In this case, the bottom surfaces S1 and S2 of the cavity 160 may have different heights depending on positions. In other words, the bottom surfaces S1 and S2 are not flat and may have a predetermined inclination angle. And, the structure of the cavity 160 as described above can increase the surface area in contact with the molding layer 190, and accordingly, bonding strength between the molding layer 190 and the circuit board 100 may be improved.

According to an embodiment, the circuit board includes a cavity. At this time, the cavity 160 has a non-penetrating structure rather than a structure penetrating the second insulating layer 120. At this time, the cavity 160 exposes the pad 141a disposed on the first insulating layer 110. Also, the bottom surface of the cavity 160 is positioned lower than the top surface of the pad 141a. Also, the cavity 160 may have the same upper width and lower width. Furthermore, the cavity 160 includes an inner wall and a bottom surface, and the height of the bottom surface may decrease from the outside to the inside. In other words, the cavity 160 may gradually increase in depth from the outside to the inside.

Accordingly, in the embodiment, it is not necessary to form an additional layer to form the cavity 160, and thus the number of processes can be reduced. In addition, in the embodiment, it is possible to solve the loss due to the thickness change or shape change of the pad 141a occurring in the process of removing the additional layer, and accordingly, product reliability can be improved.

According to an embodiment, the circuit board includes a cavity. In addition, the cavity of the circuit board has a non-penetrating structure rather than a structure penetrating the second insulating layer. In this case, the cavity exposes the pad disposed on a top surface of the first insulating layer. In this case, a bottom surface of the cavity is positioned lower than the top surface of the pad. Accordingly, in the embodiment, it is not necessary to form an additional stop layer on the top surface of the first insulating layer to form the cavity, and accordingly, it may omit processes such as the formation and removal of the stop layer. In addition, the embodiment may solve the reliability problem due to the change in thickness or shape of the pad that may occur in the process of removing the stop layer in the comparative example, and thereby improve product reliability.

In addition, the cavity of the circuit board in the embodiment includes a bottom surface and an inner wall. In this case, the bottom surface of the cavity may have different heights depending on positions. In other words, the bottom surface of the cavity may have a shape in which a height gradually decreases from the outside to the inside. According to this, when an additional molding layer is formed on the bottom surface of the cavity, a contact area with the molding layer may be increased, thereby improving product reliability.

In addition, the cavity of the circuit board in the embodiment is formed using a jig. In addition, a shape of the cavity may correspond to a shape of the jig. For example, an upper width and a lower width of the cavity may be equal to each other. In this case, an inclination angle of the inner wall of the cavity in the comparative example may be perpendicular to a main surface.

The above embodiment can reduce the inclination angle of the inner wall compared to the comparative example, and accordingly when the same device is disposed, the embodiment may minimize a space required for forming a cavity compared to the comparative example, thereby improving circuit integration. In other words, the embodiment may form the inclination angle of the inner wall substantially perpendicular, and accordingly, more circuits can be formed within the same area compared to the comparative example, and thus the overall volume of the circuit board can be reduced.

Hereinafter, a method of manufacturing a circuit board according to an embodiment will be described with reference to the accompanying drawings.

FIGS. 5 to 9 are views showing a method of manufacturing the circuit board shown in FIG. 1B in order of process

Referring to FIG. 5, the first insulating layer 110 may be prepared, and first and second circuit patterns 141 and 142 may be formed on the surface of the first insulating layer 110, and the first via V1 passing through the first insulating layer 110 and electrically connecting the first and second circuit patterns 141 and 142 may be formed.

A metal layer (not shown) is laminated on the surface of the first insulating layer 110. The metal layer may be formed by electroless plating a metal including copper on the first insulating layer 110. In addition, unlike the formation of the metal layer by electroless plating on the first insulating layer 110, copper clad laminate (CCL) may be used.

When the metal layer is formed by electroless plating, roughness is provided to the top surface of the first insulating layer 110 so that plating can be performed smoothly. Then, by patterning the metal layer, first and second circuit patterns 141 and 142 are respectively formed on the top and bottom surfaces of the first insulating layer 110. In this case, the first circuit pattern 141 may include a pad 141a connected to the electronic devices 180 and 180a to be mounted on the first insulating layer 110 later through the connection part 170.

As described above, the first and second circuit patterns 141 and 142 may be formed by an additive process, a subtractive process, a modified semi additive process (MSAP) and a semi additive process (SAP) method, which is a typical circuit board manufacturing process, and a detailed description thereof will be omitted herein.

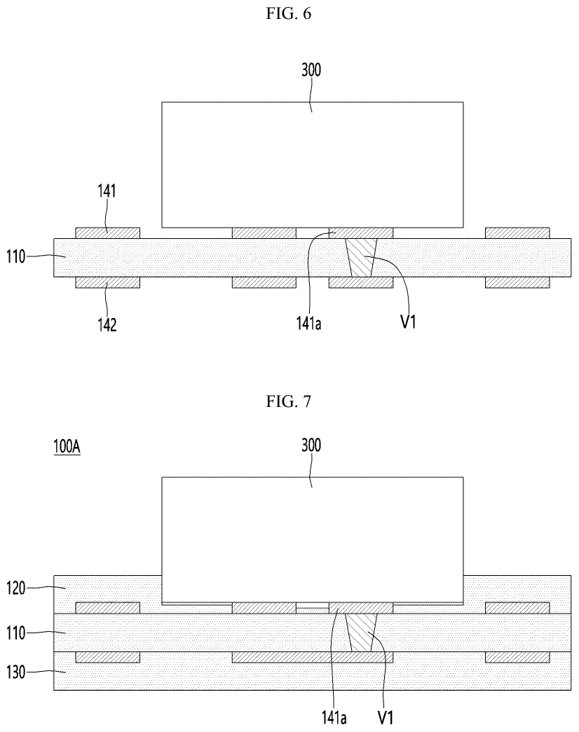

Next, referring to FIG. 6, the jig 300 may be disposed in a region where the cavity 160 is to be formed among the upper region of the first insulating layer 110. The jig 300 may have a shape corresponding to a shape that the cavity 160 should have. For example, the jig 300 may have a square shape.

The jig 300 may be formed of a material that can be easily separated from the second insulating layer 120 after the second insulating layer 120 is laminated later. For example, the jig 300 may be formed of at least one of polymer, ceramic, and metal, and may have characteristics that are easily separated from the second insulating layer 120.

Next, referring to FIG. 7, a process of laminating a second insulating layer 120 and a third insulating layer 130 may be performed at an upper portion and a lower portion of the first insulating layer 110.

In this case, the second insulating layer 120 may have a single layer. In addition, the third insulating layer 130 may also have a single layer.

In addition, the second insulating layer 120 and the third insulating layer 130 may be composed of RCC.

Accordingly, the second insulating layer 120 and the third insulating layer 130 may have a thickness of 5 μm to 20 μm. For example, when the second insulating layer 120 has a multi-layer structure, each of the plurality of layers may have a thickness of 5 μm to 20 μm. In addition, when the second insulating layer 120 has a single layer, the thickness of the single layer of the second insulating layer 120 may be 5 μm to 20 μm.

In this case, the jig 300 is disposed on the first insulating layer 110 and may substantially not contact the first insulating layer 110. That is, the pad 141a is disposed on the top surface of the first insulating layer 110, and thus the jig 300 may be positioned on the pad 141a.

Accordingly, a space corresponding to the height of the pad 141a exists between the lower surface of the jig 300 and the top surface of the first insulating layer 110.

In addition, in the process of laminating the second insulating layer 120, the second insulating layer 120 may penetrate into a space between the jig 300 and the first insulating layer 110.

Accordingly, when forming the cavity 160 in the second insulating layer 120 disposed on the first insulating layer 110, the cavity 160 of the embodiment may have a non-penetrating structure rather than a structure penetrating the second insulating layer 120. That is, a cavity in a general circuit board includes an inner wall formed on the second insulating layer 120 and a bottom surface corresponding to the top surface of the first insulating layer 110. In the embodiment, both the inner wall and the bottom surface of the cavity 160 may be formed on the second insulating layer 120.

Meanwhile, in the above, a process of laminating the second insulating layer 120 was performed after forming the jig 300. However, differently from this, the jig 300 may include an RCC layer constituting the second insulating layer 120. That is, the second insulating layer 120 including the cavity 160 may be formed by bonding the RCC layer to the jig 300 in a semi-cured state and laminating the jig 300 to which the RCC layer is bonded on the first insulating layer 110.

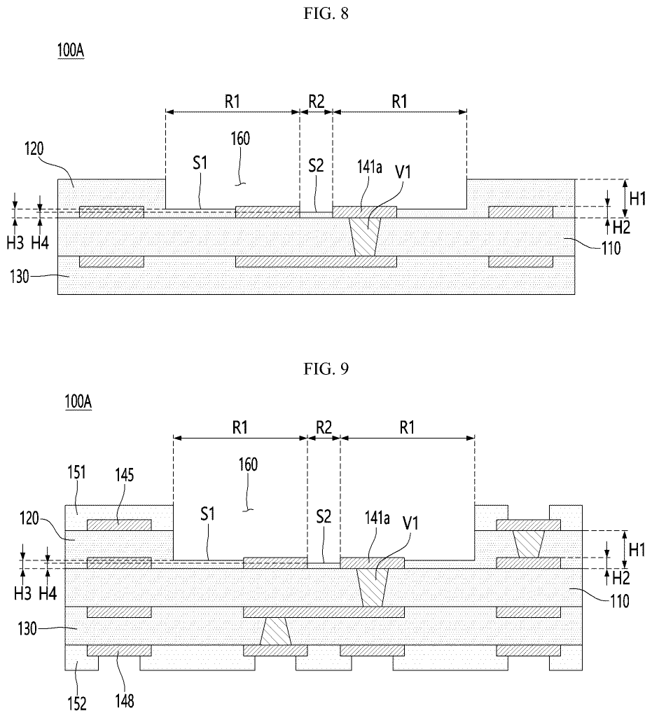

Next, referring to FIG. 8, a process of removing the jig 300 is performed in a state in which the second insulating layer 120 is laminated, so that a cavity 160 may be formed in the second insulating layer 120.

Next, referring to FIG. 9, in the embodiment, a process of forming a circuit pattern on the surface of the second insulating layer 120 may be performed.

In addition, in the embodiment, a process of forming a circuit pattern on the surface of the third insulating layer 130 may be performed.

In addition, a process of forming vias for electrically connecting circuit patterns disposed on different layers to each other may be performed in the second insulating layer 120 and the third insulating layer 130.

In addition, when the circuit patterns and vias are formed, protective layers 151 and 152 are formed on the top surface of the second insulating layer 120 and the lower surface of the third insulating layer 130.

Each of the first protective layer 151 and the second protective layer 152 may have an opening. For example, the first protective layer 151 may have an opening exposing a surface of a circuit pattern to be exposed among the circuit patterns disposed on the top surface of the second insulating layer 120.

In addition, the second protective layer 152 may have an opening exposing a surface of a circuit pattern to be exposed among the circuit patterns disposed on the lower surface of the third insulating layer 130.

Meanwhile, in the embodiment, the cavity 160A may be formed using the jig 300 in a manner different from that of the first and second embodiments.

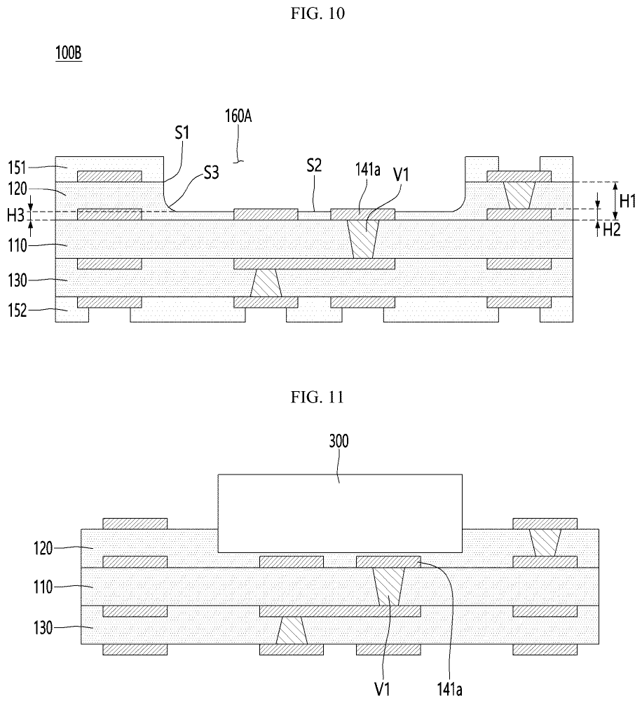

FIG. 10 is a view showing a circuit board 100B according to a third embodiment.

Referring to FIG. 10, the circuit board according to the third embodiment includes the first insulating layer 110, the second insulating layer 120, and the third insulating layer 130 as described above. In addition, the first protective layer 151 is disposed on the top surface of the second insulating layer 120, and the second protective layer 152 is disposed on the lower surface of the third insulating layer 130.

As in the third embodiment, the cavity 160A may be formed in the second insulating layer 120 composed of a single layer. However, the cavity 160A may be formed in the second insulating layer 120 composed of a plurality of layers.

Meanwhile, the cavity 160A in the circuit board 100B in the third embodiment may be formed without penetrating the second insulating layer 120.

In other words, the second insulating layer 120 may include a first portion where the cavity 160A is formed and a second portion excluding the first portion. In addition, the thickness H3 of the first portion may be different from the thickness H1 of the second portion.

Preferably, the thickness H1 of the second portion may correspond to the thickness of the second insulating layer 120.

The second portion may have a thickness of 5 μm to 20 μm. For example, the thickness of the second portion corresponds to the thickness of the second insulating layer 120 composed of one layer of RCC, and thus may have a thickness of 5 μm to 20 μm.

A thickness H3 of the first portion may be smaller than a thickness H1 of the second portion. The thickness H3 of the first portion may be determined by the thickness H2 of the pad 141a. Preferably, the thickness H3 of the first portion may be smaller than the thickness H2 of the pad 141a.

Preferably, the thickness H2 of the pad 141a may be smaller than the thickness H1 of the second portion. For example, the thickness H2 of the pad 141a may be 5 μm to 10 μm.

In addition, the thickness H3 of the first portion may be smaller than the thickness H2 of the pad 141a. For example, the thickness H3 of the first portion may be 3 μm to 8 μm. Thus, the first portion of the second insulating layer 120 is disposed on the first insulating layer 110. In this case, the first portion of the second insulating layer 120 may expose an top surface of the pad 141a disposed on the first insulating layer 110.

That is, in order to mount the electronic device in the embodiment, the cavity 160A does not pass through the second insulating layer 120, and the cavity 160 is formed while at least a portion of the second insulating layer 120 remains on the first insulating layer 110.

In this case, the thickness H3 of the remaining part of the second insulating layer 120 is smaller than the thickness H2 of the pad 141a to be exposed on the cavity 160. Accordingly, in the embodiment, the cavity 160 may be formed while maintaining the shape of the pad 141a without affecting the mounting of the electronic device on the pad 141a.

The cavity 160A includes an inner wall S1, a bottom surface S2, and an edge surface S3 between the inner wall S1 and the bottom surface S2.

The inner wall S1 may be perpendicular to the top or bottom surface of the second insulating layer 120. In addition, the bottom surface S2 may be parallel to the top or bottom surface of the second insulating layer 120.

In addition, the edge surface S3 may connect the inner wall S1 and the bottom surface S2. In this case, the edge surface S3 may have a curved surface that is not perpendicular. That is, the cavity 160A in the embodiment may be formed by performing an additional process in a state in which a groove G having a certain depth is formed in the second insulating layer 120 using the jig 300. In this case, the additional process may include, for example, a desmear process.

Here, when the desmear process is performed, chemical etching is performed in the desmear process, so that a compensation region between the jig 300 and the cavity 160A needs to be set. For example, the groove G formed through the jig 300 may have a region smaller than that of the cavity 160A.

In this case, when the desmear process is performed, it is relatively difficult for the etchant to penetrate the corner portion of the cavity 160A more than the inner wall S1 of the cavity 160A, and accordingly, the edge surface S3 of the cavity 160A may have a curved surface.

In addition, the bottom surface S2 of the cavity 160A may have a certain roughness according to a desmear process. In addition, the roughness of the bottom surface S2 can improve bonding strength with a later molding layer. For example, the bottom surface S2 may have a certain curve according to a desmear process.

The bottom surface S2 may have a third height H3. That is, the pad 141a may have a second height H2. In addition, the bottom surface S2 may have a third height H3 smaller than the second height H2.

The third height H3 of the bottom surface S2 may have a level ranging from 30% to 95% of the second height H2.

That is, in the circuit board 100B in the third embodiment according to FIG. 10, the second insulating layer 120 is composed of a single RCC layer, and a cavity 160A is formed in the single-layer second insulating layer 120. In this case, the cavity 160A may be formed through a desmear process performed after the press process of the jig 300, and accordingly, the cavity 160A may include the inner wall S1, the bottom surface S2, and the curved edge surface S3.

FIGS. 11 to 14 are views illustrating a method of manufacturing the circuit board shown in FIG. 10 in order of process.

Referring to FIG. 11, a first insulating layer 110 may be prepared, first and second circuit patterns 141 and 142 may be formed on a surface of the first insulating layer 110, and a first via V1 passing through the first insulating layer 110 and electrically connecting the first and second circuit patterns 141 and 142 may be formed.

In this case, the first circuit pattern 141 may include a pad 141a connected to the electronic devices 180 and 180a to be mounted on the first insulating layer 110 later through a connection portion 170.

When the first insulating layer 110 is formed, a process of stacking the second insulating layer 120 on the top surface of the first insulating layer 110 and stacking the third insulating layer 130 on the lower surface of the first insulating layer 110 may be performed. In addition, a process of forming circuit patterns on the top surface of the second insulating layer 120 and the lower surface of the third insulating layer 130 may be performed. In addition, a process of forming vias inside the second insulating layer 120 and inside the third insulating layer 130 may be performed.

Accordingly, the second insulating layer 120 and the third insulating layer 130 may have a thickness of 5 μm to 20 μm. For example, when the second insulating layer 120 has a structure of a plurality of layers, each of the plurality of layers may have a thickness of 5 μm to 20 μm. In addition, when the second insulating layer 120 has a single layer, the thickness of the single layer of the second insulating layer 120 may be 5 μm to 20 μm.

Meanwhile, a process of pressing the second insulating layer 120 using the jig 300 may be performed in the state where the second insulating layer 120 and the third insulating layer 130 are disposed on the first insulating layer 110 as described above.

That is, the jig 300 may be positioned on the second insulating layer 120, and a press process of the jig 300 may be performed accordingly.

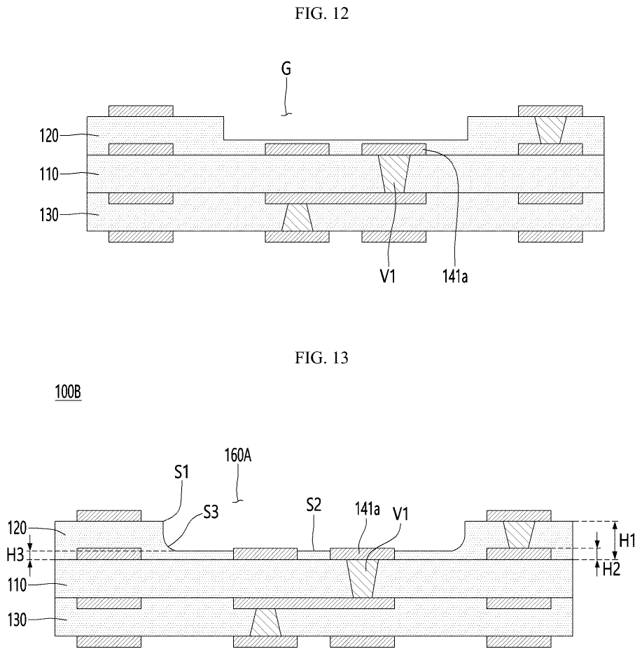

Accordingly, as shown in FIG. 12, a groove G having a predetermined depth may be formed in the second insulating layer 120. In this case, an area of the groove G may be smaller than an area of the cavity 160A formed in the second insulating layer 120.

The jig 300 may be formed of a material that can be easily separated from the second insulating layer 120 after the second insulating layer 120 is laminated later. For example, the jig 300 may be formed of at least one of polymer, ceramic, and metal, and may have characteristics that are easily separated from the second insulating layer 120.

Next, as shown in FIG. 13, a cavity 160A may be formed in the second insulating layer 120 by additionally processing the formed groove G. The additional process may include a desmear process, but is not limited thereto.

That is, the cavity 160A formed by performing the press process and the desmear process using a jig may be formed without penetrating the second insulating layer 120.

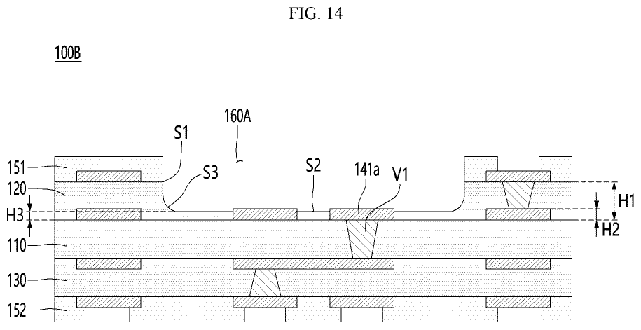

Next, as shown in FIG. 14, when the cavity 160A is formed, protective layers 151 and 152 are formed on the top surface of the second insulating layer 120 and the bottom surface of the third insulating layer 130.

In addition, in the embodiment, a combination shape of the second embodiment and the third embodiment is also possible. For example, a desmear process may be additionally performed on the cavity according to the second embodiment so that the cavity includes a curved edge surface between the inner wall and the bottom surface.

According to an embodiment, the circuit board includes a cavity. In addition, the cavity of the circuit board has a non-penetrating structure rather than a structure penetrating the second insulating layer. In this case, the cavity exposes the pad disposed on a top surface of the first insulating layer. In this case, a bottom surface of the cavity is positioned lower than the top surface of the pad. Accordingly, in the embodiment, it is not necessary to form an additional stop layer on the top surface of the first insulating layer to form the cavity, and accordingly, it may omit processes such as the formation and removal of the stop layer. In addition, the embodiment may solve the reliability problem due to the change in thickness or shape of the pad that may occur in the process of removing the stop layer in the comparative example, and thereby improve product reliability.

In addition, the cavity of the circuit board in the embodiment includes a bottom surface and an inner wall. In this case, the bottom surface of the cavity may have different heights depending on positions. In other words, the bottom surface of the cavity may have a shape in which a height gradually decreases from the outside to the inside. According to this, when an additional molding layer is formed on the bottom surface of the cavity, a contact area with the molding layer may be increased, thereby improving product reliability.

In addition, the cavity of the circuit board in the embodiment is formed using a jig. In addition, a shape of the cavity may correspond to a shape of the jig. For example, an upper width and a lower width of the cavity may be equal to each other. In this case, an inclination angle of the inner wall of the cavity in the comparative example may be perpendicular to a main surface.

The above embodiment can reduce the inclination angle of the inner wall compared to the comparative example, and accordingly when the same device is disposed, the embodiment may minimize a space required for forming a cavity compared to the comparative example, thereby improving circuit integration. In other words, the embodiment may form the inclination angle of the inner wall substantially perpendicular, and accordingly, more circuits can be formed within the same area compared to the comparative example, and thus the overall volume of the circuit board can be reduced.

Features, structures, effects, etc. described in the above embodiments are included in at least one embodiment, and are not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and modifications should be interpreted as being included in the scope of the embodiments.

In the above, the embodiment has been mainly described, but this is only an example and does not limit the embodiment, those of ordinary skill in the art to which the embodiment pertains will appreciate that various modifications and applications not illustrated above are possible without departing from the essential characteristics of the present embodiment. For example, each component specifically shown in the embodiment can be implemented by modification. And differences related to such modifications and applications should be construed as being included in the scope of the embodiments set forth in the appended claims.

1-10. (canceled)

11. A circuit board comprising:
a first insulating layer;
a plurality of pads disposed on the first insulating layer and spaced apart from each other in a horizontal direction; and
a second insulating layer disposed on the first insulating layer and including a cavity overlapping the plurality of pads in a vertical direction,
wherein the cavity includes a bottom surface positioned higher than a top surface of the first insulating layer, and an inner wall extending from an end of the bottom surface toward a top surface of the second insulating layer,
wherein the bottom surface includes:
a first region positioned between the inner wall and the plurality of pads and having a height lower than a height of top surfaces of the plurality of pads; and
a second region other than the first region positioned between the plurality of pads and having a height lower than the height of the top surfaces of the plurality of pads; and
wherein the height of the first region is different from the height of the second region.

12. The circuit board of claim 11, wherein the inner wall has a first slope, and the bottom surface has a second slope different from the first slope, and
wherein the inner wall and the bottom surface are divided based on the first slope and the second slope.

13. The circuit board of claim 11, wherein the first slope is perpendicular to a top or bottom surface of the second insulating layer.

14. The circuit board of claim 11, wherein the height of the first region is greater than the height of the second region.

15. The circuit board of claim 11, wherein at least one of the first region and the second region includes a portion whose height changes in the horizontal direction.

16. The circuit board of claim 15, wherein the height of the first region decreases as a distance from the inner wall increases.

17. The circuit board of claim 15, wherein the height of the second region decreases as a distance from the inner wall increases.

18. The circuit board of claim 15, wherein a vertical cross-sectional shape combining the first and second regions of the bottom surface has a V-shape.

19. The circuit board of claim 11, wherein a width of the cavity at an upper end of the inner wall is equal to a width of the cavity at a lower end of the inner wall.

20. The circuit board of claim 11, wherein a thickness of the second insulating layer is in a range of 5 um to 20 um.

21. The circuit board of claim 20, wherein the second insulating layer includes RCC (Resin Coated Copper).

22. The circuit board of claim 11, wherein the cavity includes an edge surface between the inner wall and the bottom surface, and
wherein the edge surface has a curved surface.

23. A package substrate comprising:
a first insulating layer;
a plurality of pads disposed on the first insulating layer and spaced apart from each other in a horizontal direction;
a second insulating layer disposed on the first insulating layer and including a cavity overlapping the plurality of pads in a vertical direction;
a connection part disposed on the plurality of pads vertically overlapping the cavity; and
an electronic device disposed on the connection part,
wherein the cavity includes a bottom surface positioned higher than a top surface of the first insulating layer, an inner wall extending from an end of the bottom surface toward a top surface of the second insulating layer, and an edge surface between the inner wall and the bottom surface,
wherein the bottom surface includes:
a first region positioned between the inner wall and the plurality of pads and having a height lower than a height of top surfaces of the plurality of pads; and
a second region other than the first region positioned between the plurality of pads and having a height lower than the height of the top surfaces of the plurality of pads;
wherein the height of the first region is different from the height of the second region, and
wherein the edge surface includes a curved surface.

24. The package substrate of claim 19, wherein the inner wall has a first slope perpendicular to a top or bottom surface of the second insulating layer, and the bottom surface has a second slope different from the first slope, and
wherein the inner wall and the bottom surface are divided based on the first slope and the second slope.

25. The package substrate of claim 23, wherein the height of the first region is greater than the height of the second region.

26. The package substrate of claim 23, wherein at least one of the first region and the second region includes a portion whose height changes in the horizontal direction.

27. The package substrate of claim 26, wherein the height of each of the first region and the second region decreases as a distance from the inner wall increases.

28. The package substrate of claim 27, wherein a vertical cross-sectional shape combining the first and second regions of the bottom surface has a V-shape.

29. The package substrate of claim 23, wherein a width of the cavity at an upper end of the inner wall is equal to a width of the cavity at a lower end of the inner wall.

30. The package substrate of claim 23, wherein the second insulating layer includes RCC (Resin Coated Copper) having a thickness in a range of 5 um to 20 um.
